(19) United States
(12) Patent Application Publication
(10) Pub. No.: US 2024/0196620 A1
(43) Pub. Date: Jun. 13, 2024

(54) MEMORY DEVICE

(71) Applicant: SK hynix Inc., Icheon-si Gyeonggi-do (KR)

(72) Inventors: Da Mi YIM, Icheon-si Gyeonggi-do (KR); Ki Hong LEE, Icheon-si Gyeonggi-do (KR); Yoo Hyun NOH, Icheon-si Gyeonggi-do (KR)

(73) Assignee: SK hynix Inc., Icheon-si Gyeonggi-do (KR)

(21) Appl. No.: 18/338,088

(22) Filed: Jun. 20, 2023

(30) Foreign Application Priority Data
Dec. 13, 2022 (KR) 10-2022-0173432

(51) Int. Cl. H10B 43/35; H10B 43/27

(52) U.S. Cl. CPC H10B 43/35; H10B 43/27

(57) ABSTRACT

A memory device includes a word line including a cell array region and a connection region extending in a first direction from the cell array region; a first select line and a second select line, spaced apart from each other in a second direction intersecting the first direction on the cell array region, the first select line and the second select line, extending onto the connection region of the word line; and an isolation pattern disposed between the first select line and the second select line. The isolation pattern includes a first sub-isolation pattern extending in the first direction and a second sub-isolation pattern extending in the second direction from the first sub-isolation pattern. The second select line is bent to surround an outside corner defined at an intersection point of the first sub-isolation pattern and the second sub-isolation pattern of the isolation pattern.

### CROSS-REFERENCE TO RELATED APPLICATION

The present application claims priority under 35 U.S.C. § 119(a) to Korean patent application number 10-2022-0173432 filed on Dec. 13, 2022, in the Korean Intellectual Property Office, the entire disclosure of which is incorporated by reference herein.

### BACKGROUND

### 1. Technical Field

The present disclosure generally relates to a memory device, and more particularly, to a memory device including select lines.

### 2. Related Art

A memory device may be classified as a volatile memory device in which stored data disappears when the supply of power is interrupted or a nonvolatile memory device in which stored data is retained even when the supply of power is interrupted.

The nonvolatile memory device may include NAND flash memory, NOR flash memory, resistive random-access memory (ReRAM), phase-change random-access memory (PRAM), magnetoresistive random-access memory (MRAM), ferroelectric random-access memory (FRAM), spin transfer torque random-access memory (STT-RAM), and the like.

A NAND flash memory device may include a memory cell array for storing data and a peripheral circuit configured to perform a program, read, or erase operation in response to a command transmitted from a memory controller.

The memory cell array may include a plurality of memory blocks, and each of the plurality of memory blocks may include a plurality of memory cells.

### SUMMARY

Some embodiments provide a memory device capable of improving the degree of integration of the memory device.

Some embodiments also provide a memory device capable of reducing a defect of the memory device.

In accordance with an embodiment of the present disclosure, a memory device includes: a word line including a cell array region and a connection region extending in a first direction from the cell array region; a first select line and a second select line, spaced apart from each other in a second direction intersecting the first direction on the cell array region, the first select line and the second select line, extending onto the connection region of the word line; and an isolation pattern disposed between the first select line and the second select line. The isolation pattern includes a first sub-isolation pattern extending in the first direction and a second sub-isolation pattern extending in the second direction from the first sub-isolation pattern. The second select line is bent to surround an outside corner defined at an intersection point of the first sub-isolation pattern and the second sub-isolation pattern of the isolation pattern.

In accordance with another embodiment of the present disclosure, a memory device includes: a word line including a cell array region and a connection region extending in a first direction from the cell array region; a first select line and a second select line, spaced apart from each other in a second direction intersecting the first direction on the cell array region, the first select line and the second select line, extending onto the connection region; and an isolation pattern disposed between the first select line and the second select line. The isolation pattern includes a first sub-isolation pattern extending in the first direction, a second sub-isolation pattern which is spaced apart from the first sub-isolation pattern in an oblique direction and extends in the second direction, and a third sub-isolation pattern connecting an end of the first sub-isolation pattern and an end of the second sub-isolation pattern to each other.

In accordance with still another embodiment of the present disclosure, a memory device includes: a first word line including a cell array region and a connection region extending in a first direction from the cell array region, the first word line being partitioned by a slit; a plurality of first sub-isolation patterns arranged to be spaced apart from each other in a second direction intersecting the first direction on the cell array region of the first word line, the plurality of first sub-isolation patterns extending onto the connection region; a plurality of second sub-isolation patterns extending in the second direction from the slit, the plurality of second sub-isolation patterns being spaced apart from each other in the first direction, the plurality of second sub-isolation patterns respectively corresponding to the plurality of first sub-isolation patterns; and a plurality of select lines disposed between the plurality of first sub-isolation patterns, the plurality of select lines extending between the plurality of second sub-isolation patterns. The plurality of first sub-isolation patterns are formed to different lengths in the first direction.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a diagram illustrating an arrangement structure of a memory cell array and a peripheral circuit.

FIG. 3 is a view illustrating a structure of a memory block.

FIG. 4 is a circuit diagram illustrating a memory block in accordance with an embodiment of the present disclosure.

FIG. 5 is a view illustrating a layout of a memory device in accordance with an embodiment of the present disclosure.

FIG. 6 is a view illustrating a layout of a memory device in accordance with an embodiment of the present disclosure.

FIG. 7 is a view illustrating a layout of an isolation pattern of a memory device in accordance with an embodiment of the present disclosure.

FIGS. 8A and 8B are views illustrating voltages applied to select lines of a memory device in accordance with an embodiment of the present disclosure.

FIGS. 9 and 10 are views illustrating a layout of a memory device in accordance with another embodiment of the present disclosure.

FIG. 11 is a diagram illustrating a Solid-State Drive (SSD) system to which a memory device of the present disclosure is applied.

FIG. 12 is a diagram illustrating a memory card system to which a memory device of the present disclosure is applied.

### DETAILED DESCRIPTION

The specific structural or functional descriptions disclosed herein are merely illustrative for the purpose of describing embodiments according to the concept of the present disclosure. The embodiments according to the concept of the present disclosure can be implemented in various forms, and should not be construed as being limited to the embodiments set forth herein.

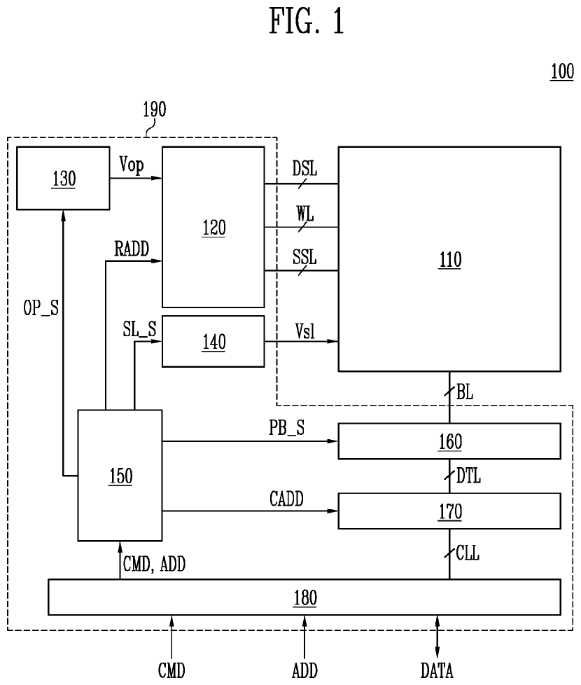

FIG. 1 is a diagram illustrating a memory device in accordance with an embodiment of the present disclosure.

Referring to FIG. 1, the memory device 100 may include a peripheral circuit 190 and a memory cell array 110.

The peripheral circuit 190 may be configured to perform a program operation and a verify operation, which are used to store data, to perform a read operation for outputting data stored in the memory cell array 110, or to perform an erase operation for erasing data stored in the memory cell array 110. The peripheral circuit 190 may include a voltage generating circuit 130, a row decoder 120, a source line driver 140, a control circuit 150, a page buffer 160, a column decoder 170, and an input/output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of strings. Memory cells included in each of the strings may be electrically connected to each other through a channel. Channels included in the strings may be connected to the page buffer 160 through bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to a source line connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit lines BL. The page buffer 160 may temporarily store data DATA received through a plurality of bit lines BL in response to the page buffer control signal PB_S. The page buffer 160 may sense a voltage or current of the plurality of bit lines BL in a read operation.

The column decoder 170 may transmit data DATA input from the input/output circuit 180 to the page buffer 160 or transmit data DATA stored in the page buffer 160 to the input/output circuit 180, in response to the column address CADD. The column decoder 170 may exchange data DATA with the input/output circuit 180 through column lines CLL, and exchange data DATA with the page buffer 160 through data lines DTL.

The input/output circuit 180 may transfer, to the control circuit 150, a command CMD and an address ADD, which are transferred from an external device (e.g., a controller) connected to the memory device 100, and output data received from the column decoder 170 to the external device.

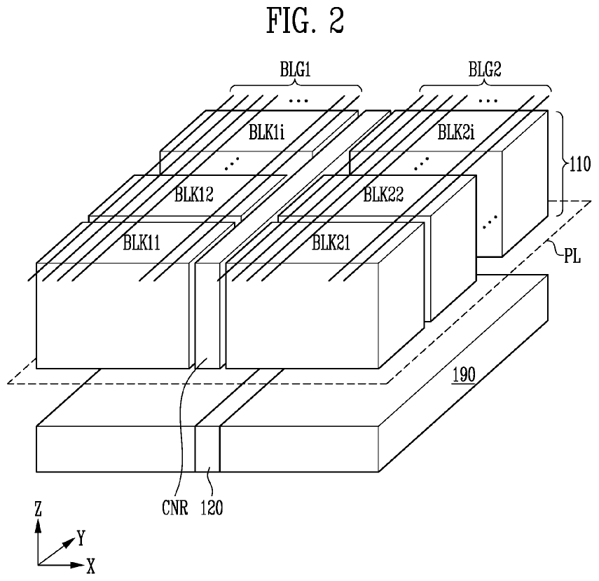

FIG. 2 is a diagram illustrating an arrangement structure of the memory cell array and the peripheral circuit.

Referring to FIG. 2, the memory cell array 110 included in the memory device may be disposed above the peripheral circuit 190. For example, the peripheral circuit 190 may be disposed above a substrate, and the memory cell array 110 may be disposed above the peripheral circuit 190.

The memory cell array 110 may include a plane PL including a plurality of memory blocks BLK11 to BLK2i (i is a positive integer). For example, the plane PL may be a region in which memory blocks sharing a source line are disposed. The plurality of memory blocks BLK11 to BLK2i may be disposed along an X direction and a Y direction. For example, a plurality of first to ith memory blocks BLK11 to BLK1i of a first group may be disposed along the Y direction, and a plurality of first to ith memory blocks BLK21 to BLK2i of a second group may be disposed along the Y direction. A first bit line group BLG1 may be connected to the plurality of first to ith memory blocks BLK11 to BLK1i of the first group, and a second bit line group BLG2 may be connected to the plurality of first to ith memory blocks BLK21 to BLK2i of the second group. A plurality of bit lines may be included in each of the first and second bit line groups BLG1 and BLG2. The plurality of first to ith memory blocks BLK11 to BLK1i of the first group and the plurality of first to ith memory blocks BLK21 to BLK2i of the second group may be disposed to be spaced apart from each other along the X direction.

Contacts for connecting the memory blocks and the peripheral circuit 190 to each other may be formed in a connection region CNR between plurality of first to ith memory blocks BLK11 to BLK1i of the first group and the plurality of first to ith memory blocks BLK21 to BLK2i of the second group. The row decoder 120 included in the peripheral circuit 190 may be disposed under the connection region CNR. The row decoder 120 may be connected to the plurality of memory blocks BLK11 to BLK2i through the contacts.

According to a connection structure between the plurality of memory blocks BLK11 to BLK2i and the row decoder 120, the plurality of memory blocks BLK11 to BLK2i may be individually selected, or a memory block of the first group and a memory block of the second group, which form a pair, may be simultaneously selected. In an embodiment, in a program, read or erase operation, memory blocks adjacent to each other in the X direction may be simultaneously selected. For example, the first memory block BLK11 of the first group and the first memory block BLK21 of the second group may be simultaneously selected. The second to ith memory blocks BLK12 to BLK1i of the first group and the second to ith memory blocks BLK22 to BLK2i may be unselected.

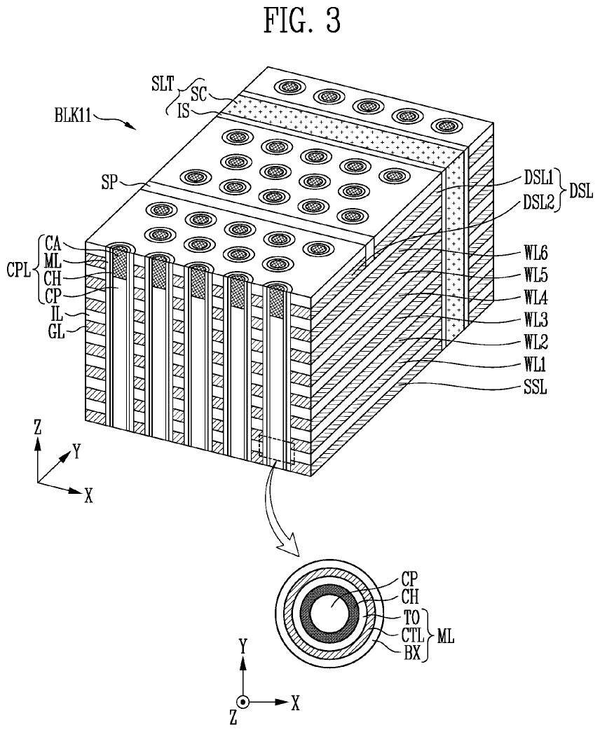

FIG. 3 is a view illustrating a structure of a memory block.

Referring to FIG. 3, to describe the structure of the memory block, the first memory block BLK11 of the first group among the plurality of memory blocks BLK11 to BLK2i shown in FIG. 2 is illustrated as an example.

The first memory block BLK11 of the first group may include insulating layers IL and gate lines GL, which are alternately stacked on a lower structure (not shown), and include cell plugs CPL vertically penetrating the insulating layers IL and the gate lines GL. For example, the lower structure may be a source line (not shown). The source line may be formed above the peripheral circuit, and the peripheral circuit may be formed above the substrate. The gate lines GL may include a source select line SSL, word lines WL1 to WL6, and drain select lines DSL1 and DSL2. FIG. 3 is a perspective view briefly illustrating the structure of the memory block, and therefore, numbers of the source select line SSL, the word lines WL1 to WL6, and the drain select lines DSL are not limited to the numbers shown in FIG. 3.

The insulating layers IL may be formed of an oxide layer or a silicon oxide layer, and the gate lines GL may be formed of a conductive layer. For example, the gate lines GL may be formed of at least one of tungsten (W), cobalt (Co), nickel (Ni), molybdenum (Mo), silicon (Si), or poly-silicon (poly-Si).

Each of the cell plugs CPL may include a memory layer ML, a channel layer CH, and a core plug CP. For example, the core plug CP extending in a Z direction may be formed at the center of the cell plug CPL. The channel layer CH may be formed to surround a side surface of the core plug CP, and the memory layer ML may be formed to surround a side surface of the channel layer CH. The core plug CP may be formed of an insulating layer or a conductive layer. The channel layer CH may be formed of a doped silicon layer. The memory layer ML may include a tunnel insulating layer TO, a charge trap layer CTL, and a blocking layer BX. The tunnel insulating layer TO may be formed to surround the side surface of the channel layer CH, and be formed of an oxide layer or a silicon oxide layer. The charge trap layer CTL may be formed to surround a side surface of the tunnel insulating layer TO, and be formed of a material capable of trapping charges. For example, the charge trap layer CTL may be formed of a nitride layer. The blocking layer BX may be formed to surround a side surface of the charge trap layer CTL, and be formed of an oxide layer or a silicon oxide layer. Each of the cell plugs CPL may further include a capping layer CA formed on the top of the core plug CP. The capping layer CA may be formed of a doped silicon layer. The capping layer CA may be formed at a level at which the drain select lines DSL are disposed.

The first memory block BLK11 of the first group may further include an isolation pattern SP. The isolation pattern SP may isolate select lines among the gate lines GL. In an embodiment, the isolation pattern SP may isolate the drain select line DSL into first and second drain select lines DSL1 and DSL2. In this specification, for convenience of description, the drain select line DSL among the select lines isolated by the isolation pattern SP is described as an embodiment. The isolation pattern SP may penetrate the drain select line DSL to isolate the drain select line DSL into the first and second drain select lines DSL1 and DSL2.

The memory block BLK11 of the first group may be distinguished from an adjacent memory block by a slit SLT. The source select line SSL, the word lines WL1 to WL6, and the drain select lines DSL, which are included in the first memory block BLK11 of the first group, may be spaced apart from a source select line SSL, word lines WL1 to WL6, and drain select lines DSL, which are included in a memory block (e.g., the first memory block of the second group) adjacent to the first memory block BLK11 of the first group, by the slit SLT. The slit SLT may include a slit insulating layer IS and a source contact SC. The slit insulating layer IS may electrically block memory blocks. The source contact SC may be in contact with the source line (not shown) formed under the memory blocks, and transfer a source line voltage generated by the voltage generating circuit to the source line.

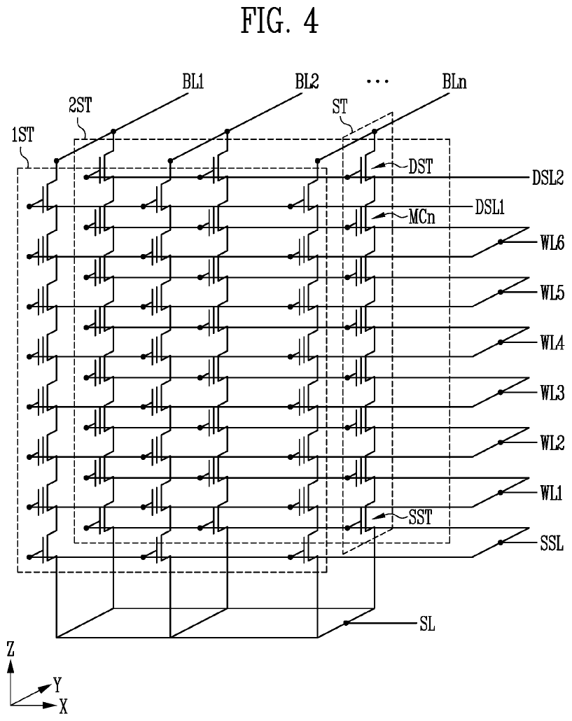

FIG. 4 is a circuit diagram illustrating a memory block in accordance with an embodiment of the present disclosure.

Referring to FIG. 4, the first memory block BLK11 of the first group may include strings ST disposed in the X and Y directions. The strings ST may be connected between bit lines BL1 to BLn and a source line SL. Each of the strings may include at least one source select transistor SST, memory cells MC, and at least one drain select transistor DST, which are arranged in the Z direction. For example, the source select transistor SST may be connected between the source line SL and the memory cells, and the drain select transistor DST may be connected between the memory cells MC and a corresponding bit line among the bit lines BL1 to BLn. A gate of the source select transistor SST may be connected to a source select line SSL, gates of the memory cells MC may be connected to word lines WL, and a gate of the drain select transistor DST may be connected to a drain select line DSL1 or DSL2 corresponding thereto. The source select line SSL may extend along an XY plane to be connected to a plurality of strings ST. The word lines WL may be arranged above the source select line SSL to be spaced apart from each other in the Z direction. Each of the word lines WL may extend along an XY plane to be connected to a plurality of strings ST. Drain select lines DSL1 and DSL2 of each memory block (e.g., BLK11) may overlap with each word line WL, and be isolated from each other at the same level. In an embodiment, the drain select lines DSL1 and DSL2 may include a first drain select line DSL1 and a second drain select line DSL2, which are disposed at the same level. A plurality of strings ST connected in parallel to each word line WL may include a plurality of first strings 1ST connected in parallel to the first drain select line DSL1 and second strings 2ST connected in parallel to the second drain select line DSL2.

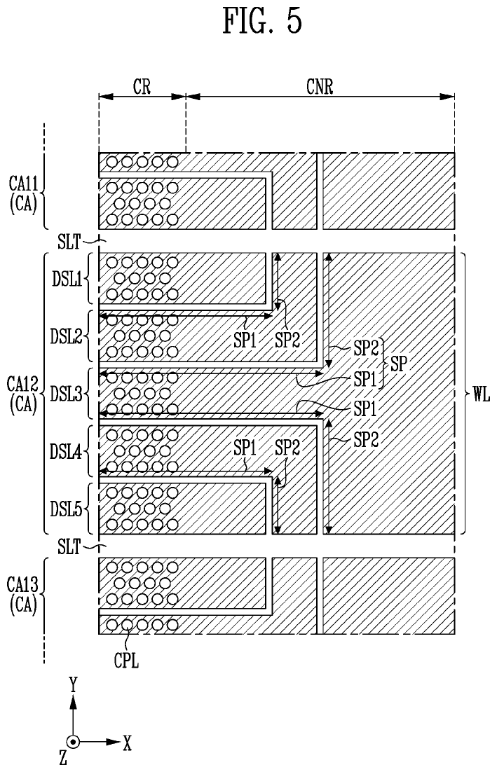

FIG. 5 is a view illustrating a layout of a memory device in accordance with an embodiment of the present disclosure.

Referring to FIG. 5, the memory device may include a plurality of memory cell arrays CA11, CA12, and CA13. The plurality of memory cell arrays CA11, CA12, and CA13 may be distinguished from each other by slits SLT. Hereinafter, to describe the structure of the memory cell array CA, the memory cell array CA12 is described as an embodiment.

Each of the memory cell arrays CA may include a plurality of gate lines stacked to be spaced apart from each other in the Z direction. In an embodiment, the memory cell array CA12 may include word lines WL and drain select lines DSL1 to DSL5. The plurality of gate lines may include a plurality of word lines WL stacked to be spaced apart from each other in the Z direction and a plurality of drain select lines DSL1 to DSL5 which overlap with the plurality of word lines WL and are spaced apart from each other on an XY plane. The plurality of word lines WL of the memory cell array CA may be partitioned by the slit SLT as described with reference to FIG. 3. The plurality of word lines WL may include a cell array region CR and a connection region CNR extending a first direction from the cell array region CR. In an embodiment, the first direction may be the X direction.

In an embodiment, the plurality of drain select lines DSL1 to DSL5 of the memory cell array CA12 may be isolated from each other on an XY plane by a plurality of isolation patterns SP. Each of the word lines WL is not penetrated by the plurality of isolation patterns SP, but may continuously extend on an XY plane to overlap with the plurality of isolation patterns SP and the plurality of drain select lines DSL1 to DSL5.

A plurality of cell plugs may extend in the Z direction to penetrate the cell array region CR of the plurality of word lines WL and the plurality of drain select lines DSL1 to DSL5. Although not shown in the drawing, some of the plurality of cell plugs CPL may overlap with a plurality of first sub-isolation patterns SP1 and a plurality of second sub-isolation patterns SP2. The plurality of cell pugs CPL may be disposed to be spaced apart from each other in the X direction in which the plurality of drain select lines DSL1 to DSL5 extend. Specifically, the plurality of cell pugs CPL may be disposed in the cell array region CR and the connection region CNR. For simplification of illustration, cell plugs CPL formed in the connection region CNR are omitted in FIGS. 5 to 10, and only some of the cell plugs CPL disposed in the cell array region CR are illustrated. Each cell plug CPL may include the memory layer ML, the channel layer CH, and the core plug CP, which are shown in FIG. 3.

The plurality of isolation patterns SP may be divided into a plurality of first sub-isolation patterns SP1 and a plurality of second sub-isolation patterns SP2. The plurality of first sub-isolation patterns SP1 may be disposed on the cell array region CR of the plurality of word lines WL, and be arranged to be spaced apart from each other in a second direction intersecting the first direction. In an embodiment, the first direction may be the X direction, and the second direction may be the Y direction. Each first sub-isolation pattern SP1 may extend along the first direction, and extend onto the connection region CNR of the plurality of word lines WL. The plurality of second sub-isolation patterns SP2 may respectively correspond to the plurality of first sub-isolation patterns SP1, and extend in the second direction (e.g., the Y direction) from the slit SLT. The plurality of second sub-isolation patterns SP2 may be spaced apart from each other in the first direction (e.g., the X direction).

The plurality of first sub-isolation patterns SP1 may be formed longer in the first direction (e.g., the X direction) as becoming more distant in the second direction (e.g., the Y direction) from the slit SLT. The plurality of first sub-isolation patterns SP1 may include ends disposed on the connection region CNR of the plurality of word lines WL.

The plurality of second sub-isolation patterns SP2 may be individually connected to the ends of the plurality of first sub-isolation patterns SP1. Accordingly, each of the isolation patterns SP may be formed in a square corner having a “ [symbol] ” shape. However, embodiments of the present disclosure are not limited thereto, and a third sub-isolation pattern may be additionally disposed between a first sub-isolation pattern SP1 and a second sub-isolation pattern SP2, which correspond to each other. The third sub-isolation pattern will be described in detail with reference to embodiments which will be described later.

The plurality of drain select lines DSL1 to DSL5 may be isolated from each other in the second direction (e.g., the Y direction) with the first sub-isolation patterns SP1 interposed therebetween, and be isolated from each other in the first direction (e.g., the X direction) with the second sub-isolation patterns SP2 interposed therebetween.

The plurality of drain select lines DSL1 to DSL5 may include a slit-side drain select line between the slit SLT and a first sub-isolation pattern SP1 adjacent thereto. In an embodiment, the plurality of drain select lines may include first to fifth drain select lines DSL1 to DSL5, and the first drain select line DSL1 and the fifth drain select line DSL5 may be provided as slit-side select lines. The first drain select line DSL1 may be symmetrical to the fifth drain select line DSL5 with respect to the third drain select line DSL3, and the second drain select line DSL2 may be symmetrical to the fourth drain select line DSL4 with respect to the third drain select line DSL3. The second drain select line and the fourth drain select line DSL4 may extend between second sub-isolation patterns SP2 adjacent to each other from first sub-isolation patterns SP1 adjacent to each other.

The plurality of memory cell arrays CA may respectively constitute a plurality of memory blocks. Alternatively, two or more memory cell arrays CA adjacent to each other in the X direction may constitute one memory block.

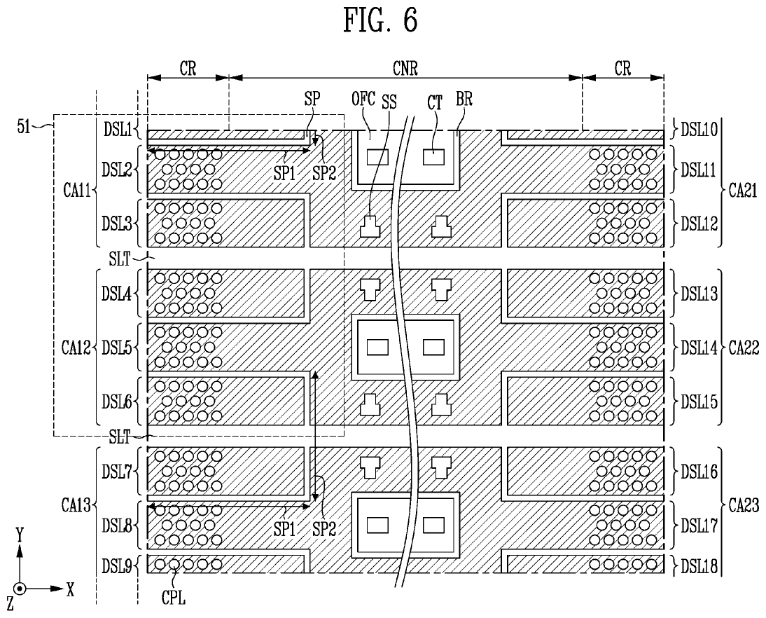

FIG. 6 is a view illustrating a layout of a memory device in accordance with an embodiment of the present disclosure.

Referring to FIG. 6, the memory device may include a plurality of cell arrays CA11, CA12, CA13, CA21, CA22, and CA23 disposed to be spaced apart from each other in the X direction and the Y direction. Each of the plurality of cell arrays CA11, CA12, CA13, CA21, CA22, and CA23 may include a word line including a cell array region CR and a connection region CNR as described with reference to FIG. 5. Each of drain select lines DSL1 to DSL18 of the plurality of cell arrays CA11, CA12, CA13, CA21, CA22, and CA23 may isolated from each other by an isolation pattern SP on a connection region CNR of a word line corresponding thereto.

The plurality of cell arrays CA11, CA12, CA13, CA21, CA22, and CA23 may be divided into a first group and a second group, which are adjacent to each other in the X direction. FIG. 5 illustrates first to third cell arrays CA11, CA12, and CA13 of the first group and first to third cell arrays CA21, CA22, and CA23 of the second group, which are adjacent thereto in the X direction. The first to third cell arrays CA11, CA12, and CA13 of the first group may be disposed to be spaced apart from each other in the Y direction. The first to third cell arrays CA11, CA12, and CA13 of the first group may be distinguished from each other by slits SLT therebetween. Similarly, the first to third cell arrays CA21, CA22, and CA23 of the second group may be disposed to be spaced apart from each other in the Y direction, and be distinguished from each other by the slits SLT therebetween.

The first to third cell arrays CA21, CA22, and CA23 of the second group may be formed in a structure symmetrical to the first to third cell arrays CA11, CA12, and CA13 of the first group with connection regions CNR interposed therebetween. A barrier insulating layer BR may be disposed in each connection region CNR. The barrier insulating layer BR may extend in the Z direction, and an opening OFC for peripheral circuit contacts CT may be defined by the barrier insulating layer BR. The peripheral circuit contacts CT may be connected to the peripheral circuit including the row decoder and the like, to extend in the Z direction. Each connection region CNR may be penetrated by a support structure SS.

Although it is illustrated that first to third drain select lines DSL1 to DSL3 included in the first cell array CA11 of the first group and fourth to sixth drain select lines DSL4 to DSL6 included in the second cell array CA12 of the first group are formed symmetrically to each other in the Y direction with respect to the slit SLT, the present disclosure is not limited to the embodiment shown in the drawing. For example, first and second sub-isolation patterns SP1 and SP2 which isolate the first to third drain select lines DSL1 to DSL3 from each other may be formed symmetrically or asymmetrically to first and second sub-isolation patterns SP1 and SP2 which isolate the fourth to sixth drain select lines DSL4 to DSL6 from each other in the Y direction with respect to the slit SLT.

Hereinafter, the structure of each cell array will be described in detail based on the first cell array CA11 of the first group.

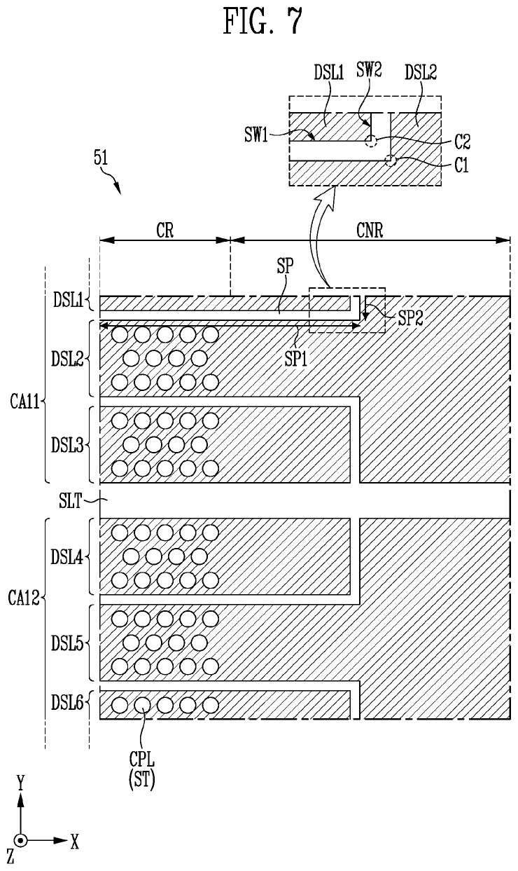

FIG. 7 is a view illustrating a layout of an isolation pattern of a memory device in accordance with an embodiment of the present disclosure.

FIG. 7 is an enlarged view of first and second cell array regions 51 of the first group shown in FIG. 6.

Referring to FIG. 7, the cell array CA11 of the first group may include a plurality of select lines DSL1 to DSL3 spaced apart from each other on an XY plane. The plurality of select lines DSL1 to DSL3 may extend onto the connection region CNR from the cell array region CR of the word line. The plurality of drain select lines DSL1 to DSL3 may be provided as drain select lines. The plurality of drain select lines DSL1 to DSL3 may be arranged to be spaced apart from each other in a direction, e.g., the Y direction intersecting a direction in which the connection region CNR extends from the cell array region CR. The plurality of drain select lines DSL1 to DSL3 may include first and second drain select lines DSL1 and DSL2 spaced part from each other with an isolation pattern SP interposed therebetween and second and third drain select lines DSL2 and DSL3 spaced apart from each other with an isolation pattern SP interposed therebetween.

The isolation patterns SP may include first and second sub-isolation patterns SP1 and SP2. The first sub-isolation pattern SP1 may extend in one direction, e.g., the X direction from the cell array region CR to the connection region CNR, and the second sub-isolation pattern SP2 may extend in a direction, e.g., the Y direction intersecting the direction in which the first sub-isolation pattern SP1 extend. The second sub-isolation pattern SP2 and the first sub-isolation pattern SP1 may be formed such that ends of the second sub-isolation pattern SP2 and the first sub-isolation pattern SP1 are connected to each other. For example, the end of the second sub-isolation pattern SP2 may be connected to the end of the first sub-isolation pattern SP1 in the connection region CNR, so that the isolation pattern SP includes a square corner having a ‘ [symbol] ’ or ‘ [symbol] ’ shape.

An outside corner C1 of the isolation pattern SP and an inside corner C2 of the isolation pattern SP may be defined at an intersection point formed as the ends of the first and second sub-isolation patterns SP1 and SP2. The first drain select line DSL1 may include an end surrounded by the inside corner C2 of the isolation pattern SP. The second select line DSL2 may be formed in a bent shape to surround the outside corner C1 of the isolation pattern SP. The inside or outside corner C1 or C2 of the isolation pattern SP is not limited to the right angle shape shown in the drawing. In an embodiment, the inside or outside corner C1 or C2 of the isolation pattern SP may be formed in a curved or round shape. In addition, when the inside corner C2 of the isolation pattern SP is at a right angle, the outside corner C1 of the isolation pattern SP may also be necessarily formed at the right angle. Alternately, when the inside corner C2 of the isolation pattern SP has a curved or round shape, the shape of the outside corner C1 of the isolation pattern SP is not necessarily limited to the curved or round shape. For example, when the inside corner C2 of the isolation pattern is at the right angle, the outside corner C1 of the isolation pattern SP may be formed in a curved or round shape.

The first and second drain select lines DSL1 and DSL2 may be isolated from each other in the Y direction with the first sub-isolation pattern SP1 interposed therebetween, and be isolated from each other in the X direction on the connection region CNR with the second sub-isolation pattern SP2 interposed therebetween. The first drain select line DSL1 may include a first sidewall SW1 extending along the X direction and a second sidewall SW2 extending along the Y direction. The first sidewall SW1 may extend along the X direction until the first sidewall SW1 is in contact with the inside corner C2 of the isolation pattern SP, and the second sidewall SW2 may extend along the Y direction from the inside corner C2 of the isolation pattern SP. The second drain select line DSL2 may be formed to surround the first sidewall SW1 and the second sidewall SW2 of the first drain select line DSL1 with the first and second sub-isolation patterns SP1 and SP2 interposed between the second drain select line DSL2 and the first drain select line DSL1.

The first to third drain select lines DSL1 to DSL3 included in the first cell array CA11 of the first group and the fourth to sixth drain select lines DSL4 to DSL6 included in the second cell array CA12 of the first group may be isolated from each other by a slit SLT. Although not shown in the drawing, word lines and a source select line may be formed under the first to sixth drain select lines DSL1 to DSL6, and the slit SLT may isolate word lines and a source select line, which are included in the first cell array CA11 of the first group, from word lines and a source select line, which are included in the second cell array CA12 of the first group. That is, the slit SLT may be formed in a structure penetrating the drain select line (DSL shown in FIG. 3) from the source select line SSL as shown in FIG. 3. The depth of the isolation pattern SP may be controlled not to penetrate the plurality of word lines WL1 to WL6 as shown in FIG. 3, and be formed shorter in the Z direction than the slit SLT.

Although it is illustrated that the first to third drain select lines DSL1 to DSL3 included in the first cell array CA11 of the first group and the fourth to sixth drain select lines DSL4 to DSL6 included in the second cell array CA12 of the first group are formed symmetrically to each other in the Y direction with respect to the slit SLT, the present disclosure is not limited to the embodiment shown in the drawing. For example, the first and second sub-isolation patterns SP1 and SP2 which isolate the first to third select line DSL1 to DSL3 from each other may be formed symmetrically or asymmetrically in the Y direction to the first and second sub-isolation patterns SP1 and SP2 which isolate the fourth to sixth select lines DSL4 to DSL6 from each other with respect to the slit SLT.

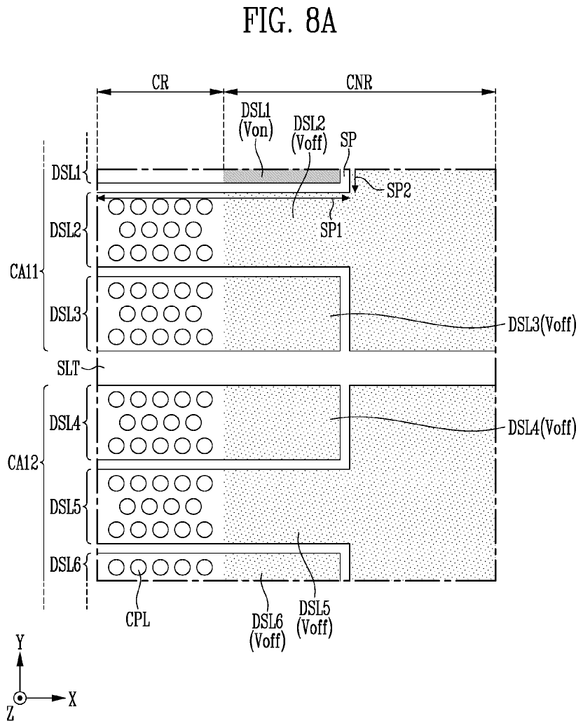

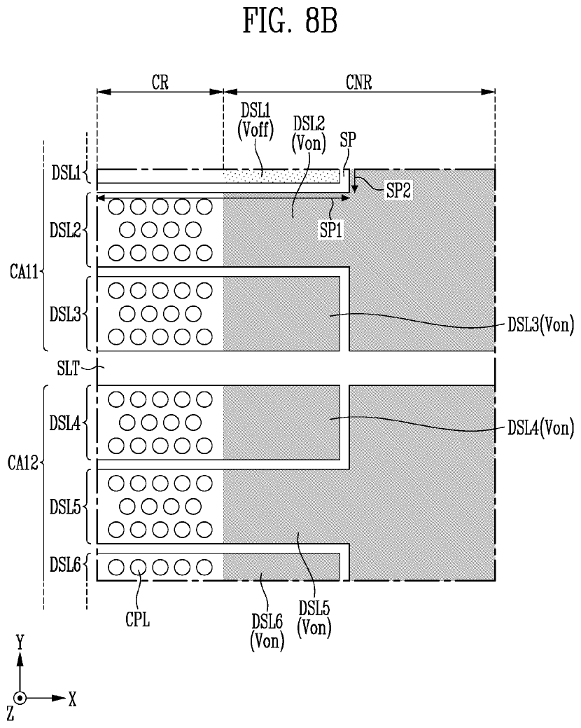

FIGS. 8A and 8B are views illustrating voltages applied to select lines of a memory device in accordance with an embodiment of the present disclosure.

Referring to FIGS. 8A and 8B, first to sixth drain select lines DSL1 to DSL6 may be electrically isolated from each other by first and second isolation patterns SP1 and SP2. Therefore, different voltages may be applied to the first to sixth drain select lines DSL1 to DSL6. For example, when a turn-on voltage Von is applied to the first drain select line DSL1, a turn-off voltage Voff may be applied to the other second to sixth drain select lines DSL2 to DSL6. When the turn-off voltage Voff is applied to the first drain select line DSL1, the turn-on voltage Von may be applied to the other second to sixth drain select lines DSL2 to DSL6.

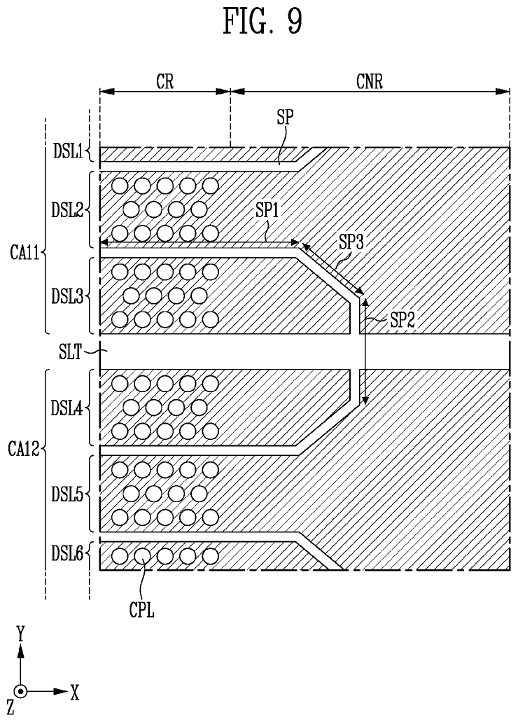

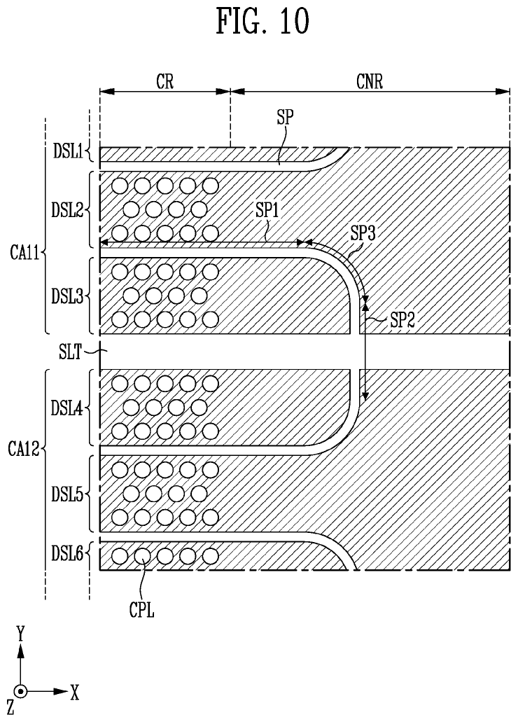

FIGS. 9 and 10 are views illustrating a layout of a memory device in accordance with another embodiment of the present disclosure.

Referring to FIGS. 9 and 10, an isolation pattern SP formed between a first drain select line DSL1 and a second drain select line DSL2 may include a first sub-isolation pattern SP1 extending in the X direction, a second sub-isolation pattern SP2 which is spaced apart from the first sub-isolation pattern SP1 in an oblique direction and extends in the Y direction, and a third sub-isolation pattern SP3 connecting end portions of the first sub-isolation pattern SP1 and the second sub-isolation pattern SP2 to each other. The third sub-isolation pattern SP3 may be formed in various shapes. For example, the third sub-isolation pattern SP3 may also be formed in a linear shape, or it may be formed in a curved or a round shape.

In accordance with the embodiments of the present disclosure, an intersection point of sub-isolation patterns constituting an isolation pattern may be defined as a double point instead of a triple point. For example, the double point may represent a point where two sub-isolation patterns are connected, and the triple point may represent a point where three sub-isolation patterns are connected. When an isolation pattern having a double point is formed, a process error can be reduced as compared with an isolation pattern having a triple point. Thus, in accordance with the embodiments of the present disclosure, a defect of the memory device can be reduced.

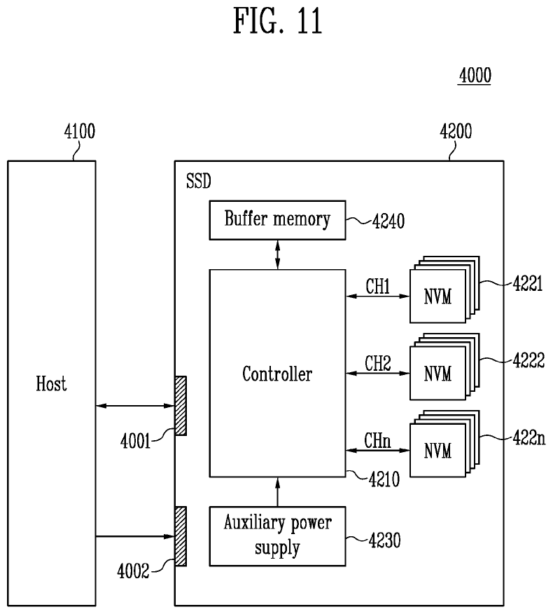

FIG. 11 is a diagram illustrating a Solid-State Drive (SSD) system to which a memory device of the present disclosure is applied.

Referring to FIG. 11, the SSD system 4000 includes a host 4100 and an SSD 4200. The SSD 4200 may exchange a signal with the host 4100 through a signal connector 4001, and be supplied with power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be transmitted based on an interface between the host 4100 and the SSD 4200. For example, the signal may be defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may be used as buffer memory of the SSD 4200. For example, the buffer memory 4240 may temporarily store data received from the host 4100 or data received from the plurality of memory devices 4221 to 422n, or temporarily store metadata (e.g., a mapping table) of the plurality of memory devices 4221 to 422n. The buffer memory 4240 may include volatile memory such as DRAM, SDRAM, DDR SDRAM, LPDDR SDRAM, and GRAM or nonvolatile memory such as FRAM, ReRAM, STT-MRAM, and PRAM.

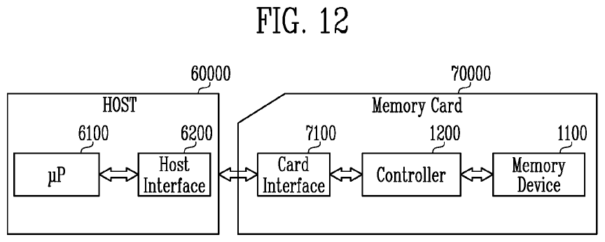

FIG. 12 is a diagram illustrating a memory card system to which a memory device of the present disclosure is applied.

Referring to FIG. 12, the memory system 70000 may be implemented as a memory card or a smart card. The memory system 70000 may include a memory device 1100, a controller 1200, and a card interface 7100.

The memory device 1100 may be configured identically to the memory device 100 shown in FIG. 1.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol.

The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor (μP) 6100.

In accordance with the present disclosure, the degree of integration of a memory device can be improved, and a defect of the memory device can be reduced.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or some of the steps may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a word line including a cell array region and a connection region extending in a first direction from the cell array region;
a first select line and a second select line, spaced apart from each other in a second direction intersecting the first direction on the cell array region, the first select line and the second select line, extending onto the connection region of the word line; and
an isolation pattern disposed between the first select line and the second select line,
wherein the isolation pattern includes a first sub-isolation pattern extending in the first direction and a second sub-isolation pattern extending in the second direction from the first sub-isolation pattern, and
wherein the second select line is bent to surround an outside corner defined at an intersection point of the first sub-isolation pattern and the second sub-isolation pattern of the isolation pattern.

2. The memory device of claim 1, wherein the first select line and the second select line:
are isolated from each other in the second direction with the first sub-isolation pattern of the isolation pattern, which is interposed therebetween; and
are isolated from each other in the first direction on the connection region with the second sub-isolation pattern of the isolation pattern, which is interposed therebetween.

3. The memory device of claim 1, wherein the first select line includes an end surrounded with an inside corner of the isolated pattern, which is defined at the intersection point of the first sub-isolation pattern and the second sub-isolation pattern.

4. The memory device of claim 1, wherein the first select line includes a first sidewall extending along the first direction and a second sidewall extending along the second direction, and
wherein the second select line surrounds the first sidewall and the second sidewall of the first select line with the isolation pattern interposed therebetween.

5. The memory device of claim 1, further comprising:
a first cell plug penetrating the cell array region of the word line and the first select line; and
a second cell plug penetrating the cell array region of the word line and the second select line.

6. The memory device of claim 1, wherein the outside corner is formed in at least one of a right angle shape, a curved shape, or a round shape.

7. The memory device of claim 3, wherein the inside corner is formed in at least one of a right angle shape, a curved shape, or a round shape.

8. A memory device comprising:
a word line including a cell array region and a connection region extending in a first direction from the cell array region;
a first select line and a second select line, spaced apart from each other in a second direction intersecting the first direction on the cell array region, the first select line and the second select line, extending onto the connection region; and
an isolation pattern disposed between the first select line and the second select line,
wherein the isolation pattern includes a first sub-isolation pattern extending in the first direction, a second sub-isolation pattern which is spaced apart from the first sub-isolation pattern in an oblique direction and extends in the second direction, and a third sub-isolation pattern connecting an end of the first sub-isolation pattern and an end of the second sub-isolation pattern to each other.

9. The memory device of claim 8, wherein the third sub-isolation pattern has at least one of a linear shape, a curved shape, or a round shape.

10. A memory device comprising:
a first word line including a cell array region and a connection region extending in a first direction from the cell array region, the first word line being partitioned by a slit;
a plurality of first sub-isolation patterns arranged to be spaced apart from each other in a second direction intersecting the first direction on the cell array region of the first word line, the plurality of first sub-isolation patterns extending onto the connection region;
a plurality of second sub-isolation patterns extending in the second direction from the slit, the plurality of second sub-isolation patterns being spaced apart from each other in the first direction, the plurality of second sub-isolation patterns respectively corresponding to the plurality of first sub-isolation patterns; and
a plurality of select lines disposed between the plurality of first sub-isolation patterns, the plurality of select lines extending between the plurality of second sub-isolation patterns,
wherein the plurality of first sub-isolation patterns are formed to different lengths in the first direction.

11. The memory device of claim 10, wherein the plurality of first sub-isolation patterns are formed longer in the first direction as becoming more distant in the second direction from the slit.

12. The memory device of claim 10, wherein the plurality of second sub-isolation patterns are individually connected to the plurality of first sub-isolation patterns.

13. The memory device of claim 10, wherein the plurality of second sub-isolation patterns are connected to ends of the plurality of first sub-isolation patterns.

14. The memory device of claim 10, further comprising a third sub-isolation pattern connecting a first sub-isolation pattern and a second sub-isolation pattern, which correspond to each other, among the plurality of first sub-isolation patterns and the plurality of second sub-isolation patterns, the third sub-isolation pattern extending in an oblique direction from the first and second directions.

15. The memory device of claim 10, further comprising a third sub-isolation pattern connecting a first sub-isolation pattern and a second sub-isolation pattern, which correspond to each other, among the plurality of first sub-isolation patterns and the plurality of second sub-isolation patterns, the third sub-isolation pattern having a curved or round shape.

16. The memory device of claim 10, wherein a shape formed as the plurality of first and second sub-isolation patterns are connected to each other is a square corner having a ‘ [symbol] ’ shape.

17. The memory device of claim 10, wherein the plurality of select lines:
are isolated from each other in the second direction with the first sub-isolation patterns of the isolation pattern, which are interposed therebetween; and
are isolated from each other in the first direction on the connection region with the second sub-isolation patterns of the isolation pattern, which are interposed therebetween.

18. The memory device of claim 10, further comprising a second word line spaced apart from the first word line in the second direction by the slit.

19. The memory device of claim 10, further comprising a second memory cell array symmetrical to a first memory cell array with respect to the slit, wherein the first memory cell array incudes the first word line, the first sub-isolation patterns, the second sub-isolation patterns, and the plurality of select lines.
